(19) United States
(12) Patent Application Publication
(10) Pub. No.: US 2024/0021755 A1
(43) Pub. Date: Jan. 18, 2024

(54) DISPLAY PANEL AND MANUFACTURING METHOD THEREOF, AND DISPLAY DEVICE

(71) Applicant: TIANMA ADVANCED DISPLAY TECHNOLOGY INSTITUTE (XIAMEN) CO., LTD., Xiamen (CN)

(72) Inventors: Jingtao GUO, Xiamen (CN); Canyuan ZHANG, Xiamen (CN); Qiang GU, Xiamen (CN); Bo ZHOU, Xiamen (CN)

(73) Assignee: TIANMA ADVANCED DISPLAY TECHNOLOGY INSTITUTE (XIAMEN) CO., LTD., Xiamen (CN)

(21) Appl. No.: 18/475,269

(22) Filed: Sep. 27, 2023

(30) Foreign Application Priority Data
Jun. 30, 2023 (CN) 202310797776.X

(51) Int. Cl. H01L 33/22; H01L 25/075; H01L 33/00

(52) U.S. Cl. CPC H01L 33/22; H01L 25/0753; H01L 33/0093; H01L 33/32

(57) ABSTRACT

A display panel, a manufacturing method thereof and a display device are provided. The method includes: forming a display panel including light emitting elements, the plurality of light emitting elements includes first color light emitting elements and second color light emitting elements. The method includes at least one of: transferring the first color light emitting elements and the second color light emitting elements by different transfer methods, growing the first color light emitting elements and the second color light emitting elements by different growth substrate patterns, or making the first color light emitting elements and the second color light emitting elements with different surface microstructures facing a light emitting surface of the display panel.

This application claims priority to Chinese Patent Application No. 202310797776.X, filed with the China National Intellectual Property Administration on Jun. 30, 2023 and entitled “DISPLAY PANEL AND MANUFACTURING METHOD THEREOF, AND DISPLAY DEVICE”, which is incorporated herein by reference in its entirety.

### FIELD

The present disclosure relates to the field of display technology, and in particular, to a display panel, a method of manufacturing the display panel, and a display device.

### BACKGROUND

As an important part of a display device, the display panel is used to realize the display function of the display device. A light emitting diode (LED) display panel uses LED chips as light emitting elements, which has low power consumption, high saturation, and a high response speed, and thus is widely used in many scenarios.

The LED display panel usually includes light emitting elements of three colors of red, green, and blue. Because different colors of light has different wavelength bands, the three types of light emitting elements has different light extraction efficiency, resulting in poor display effect of the display panel.

### SUMMARY

In order to solve the above problems or at least partly solve the above problems, the present disclosure provides a display panel, a method of manufacturing the display panel, and a display device.

The present disclosure provides a method of manufacturing a display panel, including:
forming a display panel, and the display panel includes light emitting elements, the plurality of light emitting elements includes first color light emitting elements and second color light emitting elements;
the method includes at least one of: transferring the first color light emitting elements and the second color light emitting elements by different transfer methods, growing the first color light emitting elements and the second color light emitting elements by different growth substrate patterns, or making the first color light emitting elements and the second color light emitting elements with different surface microstructures facing a light emitting surface of the display panel.

The present disclosure also provides a display panel, including:
light emitting elements, and the plurality of light emitting elements include first color light emitting elements and second color light emitting elements, a surface microstructure of the first color light emitting elements facing a light emitting surface of the display panel is different from a surface microstructure of the second color light emitting elements facing the surface microstructure of the light emitting surface of the display panel.

The present disclosure also provides a display device, including the above-mentioned display panel.

### BRIEF DESCRIPTION OF DRAWINGS

The accompanying drawings, which are incorporated in and constitute a part of this specification, illustrate embodiments consistent with the disclosure and together with the description serve to explain the principles of the disclosure.

In order to more clearly illustrate the embodiments of the present disclosure, the following will briefly introduce the drawings that need to be used in the description of the embodiments.

FIG. 1 shows a schematic plan view of a display panel provided by an embodiment of the present disclosure.

FIG. 2 shows a schematic cross-sectional view of a display panel provided by an embodiment of the present disclosure.

FIG. 3 shows a schematic diagram of a growth process of a light emitting element in an embodiment of the present disclosure.

FIG. 4 shows a schematic diagram of a growth process of a light emitting element in another embodiment of the present disclosure.

FIG. 5 shows a schematic cross-sectional view of a display panel provided by another embodiment of the present disclosure.

FIG. 6 shows a schematic diagram of a surface etching process of a light emitting element in an embodiment of the present disclosure.

FIG. 7 shows a schematic cross-sectional view of a display panel provided by another embodiment of the present disclosure.

FIG. 8 shows a schematic cross-sectional view of a display panel provided by another embodiment of the present disclosure.

FIG. 9a to FIG. 9g show schematic diagrams of transferring light emitting elements to a temporary substrate in an embodiment of the present disclosure.

FIG. 10a to FIG. 10d show schematic diagrams of transferring light emitting elements to an array substrate in an embodiment of the present disclosure.

FIG. 11 shows a schematic cross-sectional view of a display panel provided by another embodiment of the present disclosure.

FIG. 12a to FIG. 12g show schematic diagrams of transferring the light emitting element to a temporary substrate in another embodiment of the present disclosure.

FIG. 13 shows a schematic cross-sectional view of a display panel provided by another embodiment of the present disclosure.

FIG. 14 shows a schematic cross-sectional view of a display panel provided by another embodiment of the present disclosure.

FIG. 15a to FIG. 15g show schematic diagrams of transferring the light emitting element to a temporary substrate in another embodiment of the present disclosure.

FIG. 16 shows a schematic cross-sectional view of a display panel provided by another embodiment of the present disclosure.

### DETAILED DESCRIPTION OF EMBODIMENTS

In order to more clearly understand the embodiments of the present disclosure, the solutions of the present disclosure will be further described below. It should be noted that, in the case of no conflict, the embodiments of the present disclosure and the features in the embodiments can be combined with each other.

In the following description, many specific details are set forth in order to fully understand the present disclosure, but the present disclosure can also be implemented in other ways than described. The embodiments in the description are only some, rather than all of the embodiments of the invention.

In the conventional technology, the three types of light emitting elements of the display panel have different light extraction efficiency, resulting poor color display effect of the display panel.

In view of the above embodiments of the present disclosure provide a display panel and a manufacturing method thereof, and a display device, to balance the light extraction efficiency of light emitting elements of different colors, to improve the color display effect of the display panel, and thus solving the problem of poor color display effect of the display panel.

The display panel, the manufacturing method thereof, and the display device provided by the embodiments of the present disclosure are exemplarily described below with reference to the accompanying drawings.

An embodiment of the present disclosure provides a method of manufacturing a display panel, which includes forming a display panel, where the display panel includes light emitting elements, and the light emitting elements include a first color light emitting element and a second color light emitting element. The method of manufacturing the display panel includes at least one of: transferring the first color light emitting elements and the second color light emitting elements by different transfer methods, growing the first color light emitting elements and the second color light emitting elements by different growth substrate patterns, or making the first color light emitting elements and the second color light emitting elements with different surface microstructures facing a light emitting surface of the display panel.

In the embodiments of the present disclosure, by configuring the first color light emitting elements and the second color light emitting elements with different transfer methods, or with different growth substrate patterns, or with different surface microstructures on the light emitting surface, the light emitting efficiencies of the light emitting elements of different colors are more balanced, so as to improve the color display effect of the display panel, solving the problem of poor color display effect of the display panel.

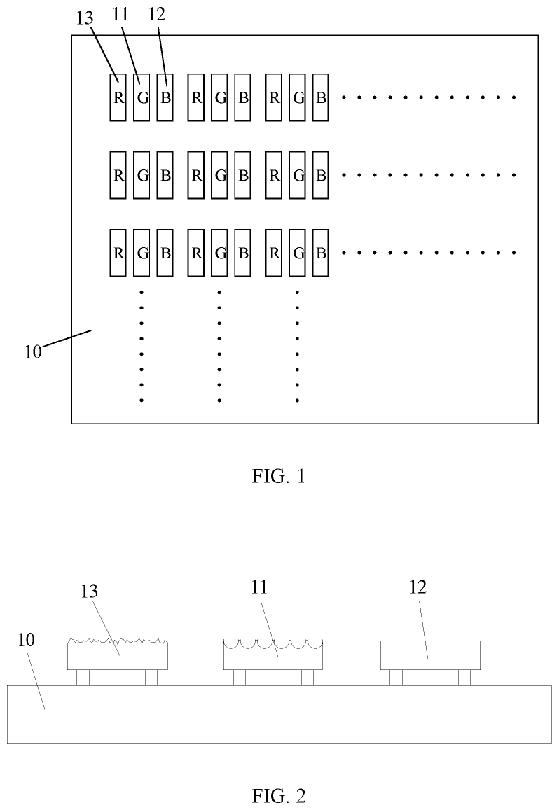

FIG. 1 shows a schematic plan view of a display panel provided by an embodiment of the present disclosure, and FIG. 2 shows a schematic cross-sectional view of a display panel provided by an embodiment of the present disclosure. In some embodiments, as shown in FIG. 1 and FIG. 2, the display panel includes an array substrate 10, light emitting elements of red (R), green (G), and blue (B) are arranged on the array substrate 10, and the green light emitting element may be referred to as a first color light emitting element 11, the blue light emitting element may be referred to as a second color light emitting element 12, and the red light emitting element may be referred to as a third color light emitting element 13.

In some embodiments, the growth substrate patterns of the first color light emitting elements and the second color light emitting elements are different, and the corresponding manufacturing method includes providing a first growth substrate and a second growth substrate, growing the first color light emitting elements on a first growth substrate, growing the second color light emitting elements on a second growth substrate, and the patterns of the first growth substrate and the second growth substrate are different.

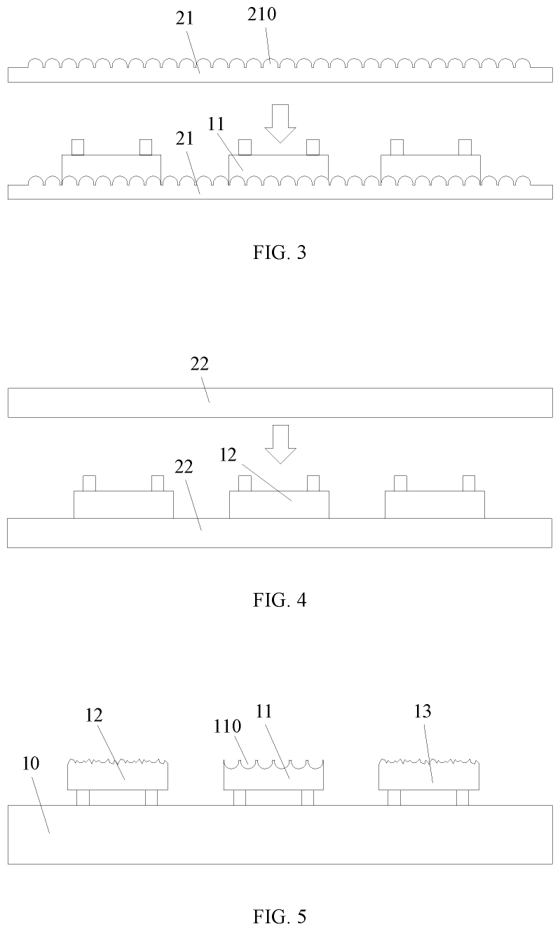

As shown in FIG. 3, a first growth substrate 21 is provided, which may be a sapphire substrate. The DPSS (Dry-etching Pattern Sapphire Substrate) technology or WPSS (Wet-etching Pattern Sapphire Substrate) technology is used to pattern the surface of the first growth substrate 21 to form a pattern of the first growth substrate 21, and then covering the pattern with a layer of gallium nitride epitaxial layer (not shown).

Then, the first color light emitting elements 11 grow on the patterned first growth substrate 21 to form the first color light emitting elements 11 with a predetermined surface microstructure.

On the other hand, as shown in FIG. 4, a second growth substrate 22 is provided. A sapphire substrate can be selected as the second growth substrate 22 and covered with a GaN epitaxial layer (not shown). The second growth substrate 22 is not patterned, but is directly used to grow the second color light emitting elements 12, to form second color light emitting elements 12 with flat surface microstructures.

The growth process of the first color light emitting element and the growth process of the second color light emitting element do not interfere with each other, and can be carried out independently without a fixed sequence.

In some embodiments, as shown in FIG. 3, the surface of the first growth substrate 21 includes protrusions 210 uniformly arranged. The surface of the first growth substrate 21 is processed into a pattern of protrusions 210, and the first color light emitting element 11 can have a surface microstructure complementary to the plurality of protrusions 210, forming a surface microstructure including pits.

After the light emitting elements of the three colors are bonded to the array substrate, the surface of the light emitting elements of the three colors is covered with a protective layer, which is usually made of GaN. The first color light emitting element 11 usually is made of sapphire. The surface microstructure of the first color light emitting element 11 can improve the lattice matching between the sapphire and the GaN, reduce the dislocation defect density of GaN, and improve the internal quantum efficiency. In addition, the surface microstructure of the first color light emitting element 11 can provide a large number of reflective surfaces with different angles. The interface between the sapphire and the GaN is prone to total reflection, resulting in a decrease in the light extraction efficiency of the light emitting elements. The large number of reflective surfaces with different angles can reflect the fully reflected light, so as to improve the external quantum efficiency and the overall luminous efficiency. Especially for the green light emitting element which has high total reflectance, the above-mentioned surface microstructure can significantly improve the luminous efficiency.

The first color light emitting elements 11 and second color light emitting elements 12 have different surface microstructures formed by different methods, for example, by growing on growth substrates with different patterns. For example, the first color light emitting elements 11 grow on the first substrate 21 with a regular pattern, which can directly obtain a special surface microstructure.

In some embodiments, the distance between adjacent protrusions 210 is of a fixed value. That is, all adjacent protrusions 210 have the same distance, and the grown first color light emitting element 11 have a relatively uniform surface microstructure, and thus have a relatively uniform light emitting effect.

In some embodiments, the maximum width of the protrusion 210 is less than or equal to 2.7 microns, and the maximum depth of the protrusion 210 is less than or equal to 1.8 microns. By setting the width of the protrusions 210 not greater than 2.7 microns, or the depth of the protrusions 210 not greater than 1.8 microns, the first color light emitting elements 11 can have sufficient protrusions 210 to emit light with a relatively uniform brightness, which can also improve the external quantum efficiency and improve the overall luminous efficiency.

In some embodiments, the surface microstructure of the first color light emitting element facing the light emitting surface of the display panel is different from the surface microstructure of the second color light emitting element facing the light emitting surface of the display panel, and different surface microstructures are used for light emitting elements of different colors, achieving selective enhancement of light efficiency. As shown in FIG. 5, the surface microstructure of the first color light emitting element 11 includes pits 110 uniformly arranged, and the surface microstructure of the second color light emitting element 12 is a roughened surface microstructure. In the embodiment, the first color light emitting element 11 is a green light emitting element, the second color light emitting element 12 is a red light emitting element, and the third color light emitting element 13 is a blue light emitting element and also has a roughened surface microstructure.

The corresponding manufacturing method includes providing a first growth substrate 21. As shown in FIG. 3, the surface of the first growth substrate 21 is patterned by a DPSS technology or a WPSS technology to form protrusions 210 uniformly arranged on the surface of the first growth substrate 21. Then the first color light emitting elements 11 are grown on the first growth substrate 21, and the first color light emitting elements 11 can have a surface microstructure including uniformly arranged pits 110.

The surface microstructure of uniformly arranged pits 110 can improve the lattice matching between the sapphire and the GaN, reduce the dislocation defect density of GaN, and improve the internal quantum efficiency. In addition, the surface microstructure can also provide a large number of reflective surfaces with different angles to reflect total reflected light, improving the external quantum efficiency and the overall luminous efficiency. Especially for green light emitting elements with high total reflectance, the luminous efficiency can be significantly improved.

In some embodiments, the distance between adjacent pits 110 is of a fixed value. That is, all adjacent pits 110 have the same distance, to form a relatively uniform surface microstructure, and the first color light emitting element 11 has a relatively uniform luminous effect.

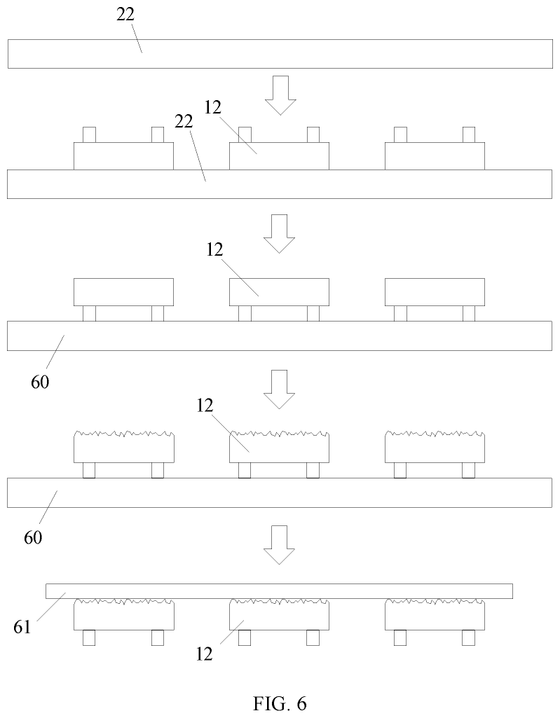

On the other hand, as shown in FIG. 6, a second growth substrate 22 is provided, which may be a gallium arsenide (GaAs) substrate. The second color light emitting elements 12 are directly grown on the second growth substrate 22 with a flat pattern to form second color light emitting elements 12 with flat surface microstructures. Then, the second color light emitting elements 12 are separated from the second growth substrate 22, and placed on a substrate 60. Then, the surface of the second color light emitting element 12 is etched to form a roughened surface microstructure, and finally through the COC (Chip on Carrier) technology, the second color light emitting element 12 is loaded on a carrier board 61 by using release adhesive.

The GaAs substrate used as the second growth substrate 22 is not suitable for adopting the DPSS technology or WPSS technology to form a patterned substrate, so the surface of the second color light emitting elements 12 grown on the second growth substrate 22 is flat. The second color light emitting elements 12 are separated from the second growth substrate 22 and then etched to form a roughened surface microstructure. The roughened surface microstructure is an irregular surface microstructure, which can also provide a large number of reflective surfaces with different angles to reflect fully reflected light, improving external quantum efficiency and luminous efficiency.

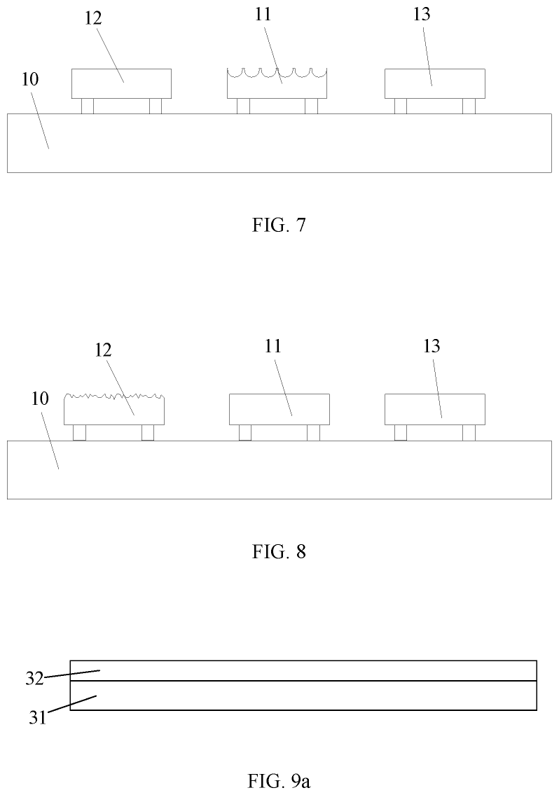

In some embodiments, as shown in FIG. 7, the surface microstructure of the first color light emitting element 11 includes pits, and the plurality of pits are uniformly arranged, and the surface microstructure of the second color light emitting element 12 and the surface microstructure of the third color light emitting element 13 are flat.

In some embodiments, as shown in FIG. 8, the surface microstructure of the second color light emitting element 12 is a roughened surface microstructure, and the surface microstructures of the first color light emitting element 11 and the third color light emitting element 13 are flat.

In the embodiment shown in FIG. 7 and FIG. 8, the surface microstructure of the first color light emitting element 11 facing the light emitting surface of the display panel is different from the surface microstructure of the second color light emitting element 12 facing the light emitting surface of the display panel, which can balance the light emitting efficiency of the color light emitting elements, and improve the color display effect of the display panel. Therefore, the problem of poor color display effect of the display panel is solved.

In some embodiments, the first color light emitting elements and the second color light emitting elements are transferred in different methods, depending on different growth methods of light emitting elements of different colors and different patterns of their growth substrates.

The corresponding production process includes providing a temporary substrate, and transferring the first color light emitting elements and the second color light emitting elements from the growth substrate to the temporary substrate, where a first transfer method is applied to the first color light emitting elements, and a second transfer method is applied to the second color light emitting elements.

When transferring the first color light emitting elements to the temporary substrate by the first transfer method, a minimum distance between the growth substrate of the first color light emitting elements and the temporary substrate is d1. When transferring the second color light emitting elements to the temporary substrate by the second transfer method, a minimum distance between the growth substrate of the second color light emitting element and the temporary substrate is d2, where d1<d2. The difference between the first transfer method and the second transfer method mainly lies in the difference in the minimum distance between the growth substrate and the temporary substrate.

In some embodiments, the first color light emitting element is a green light emitting element, the second color light emitting element is a red light emitting element, and the third color light emitting element is a blue light emitting element, the light emitting elements are LED chips, and the size of the light emitting surface of the LED chips can be 15×30 μm or 34×58 μm. The first color light emitting element is transferred to the temporary substrate firstly, and then the second color light emitting element is transferred to the temporary substrate. The transfer method is as follows.

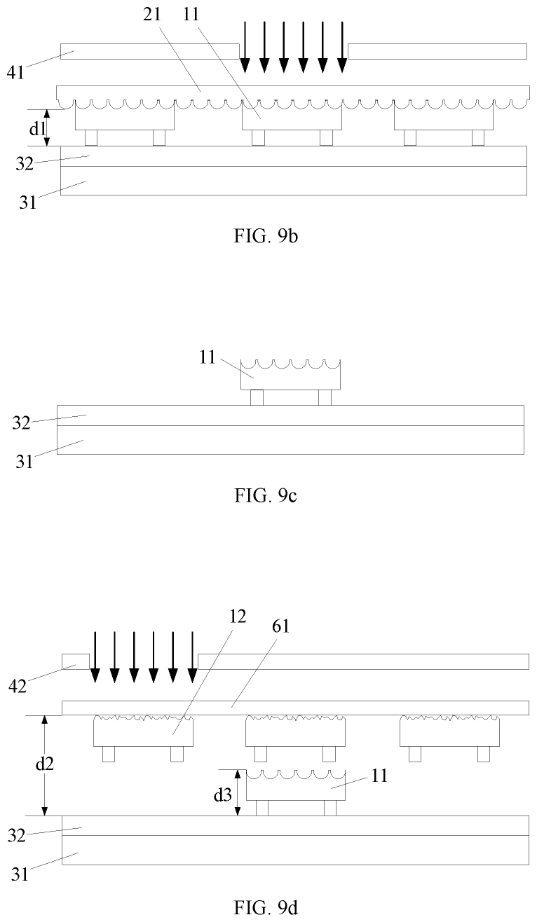

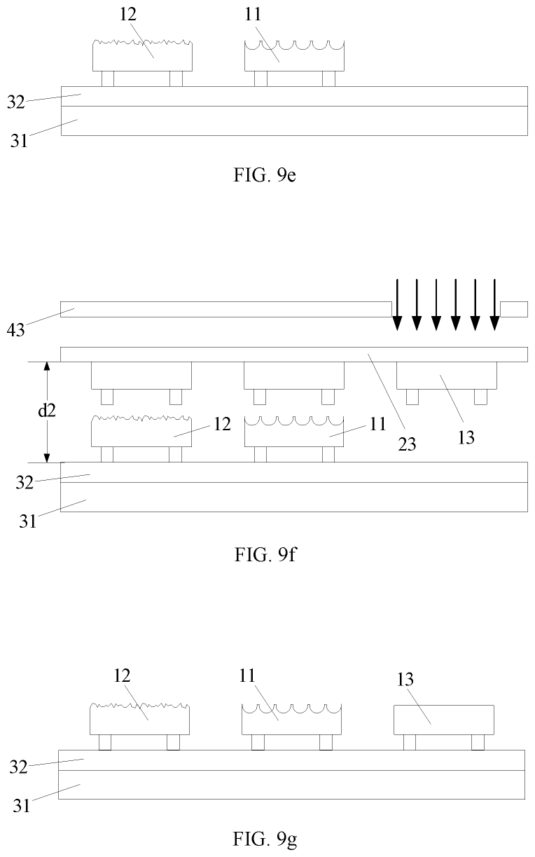

As shown in FIG. 9a, a temporary substrate is provided, and the temporary substrate includes a substrate 31 and an adhesive 32 coated on the substrate 31.

As shown in FIG. 9b, the first color light emitting elements 11 are transferred to the temporary substrate by using the first transfer method.

The first color light emitting elements 11 are densely grown on the first growth substrate 21, and only a part of the first color light emitting elements 11 need to be transferred to the temporary substrate in this step. Firstly, the COW (chip on wafer) of the first color light emitting element 11 is bound to the temporary substrate. The pressure between the first color light emitting element 11 and a contact surface is 0.01 to 0.99 MPa, and the contact time is 1 to minutes. After the binding is completed, and a minimum distance between the first growth substrate 21 and the adhesive 32 is d1.

Then a selective laser lift-off (SLLO) technology is applied by using a 248 nm excimer laser in cooperation with a mask plate (Mask) 41, to emit deep ultraviolet wavelength 248 nm laser, to peel off the first color light emitting element 11 bound to the temporary substrate. The laser spot is generally larger than one side of the first color light emitting element 11 by 1 to 2 micrometers. Alternatively, a 266 nm solid-state UV laser is used to perform galvanometer scanning without requiring a mask.

The bandgap energy width of the laser is between those of the sapphire and the GaN. The sapphire cannot absorb the laser energy, but the GaN material can strongly absorb the laser energy and generate a high temperature (about 1000° C.), which will promote the decomposition of GaN to generate Ga and N2, thus realizing the effect of laser lift-off and forming a temporary substrate as shown in FIG. 9c.

As shown in FIG. 9d, the second color light emitting element 12 is transferred to the temporary substrate by using the second transfer method.

The relatively dense second color light emitting elements 12 are carried on the carrier board 61, and only a part of them needs to be transferred to the temporary substrate in this step. The carrier board 61 is placed over the temporary substrate, a minimum distance between the carrier board 61 and the adhesive 32 is d2, and d2 can be controlled between 30 to 50 micrometers. There are corresponding position marks on the temporary substrate and the carrier board 61, and the second color light emitting element 12 can be placed on the correct position of the temporary substrate to realize accurate release. A laser with a wavelength of 248 nm, 266 nm, or 355 nm is used to cooperate with the mask plate 42 to perform SLLO on the second color light emitting element 12 at a specific position to form a temporary substrate as shown in FIG. 9e. Because the material of a binding layer between the second color light emitting element 12 and the carrier board 61 is laser-responsive adhesive material benzocyclobutene (BCB), the material can strongly absorb laser light with a wavelength of 248-355 nm.

In some embodiments, before transferring the second color light emitting element 12 to the temporary substrate through the second transfer method, the manufacturing method includes: etching the surface of the second color light emitting element 12 to form a surface microstructure (the etching and loading process is shown in FIG. 6). The second color light emitting element 12 is loaded on the carrier board 61 after etching the roughened surface microstructure. For a gap distance d2 in the SLLO process, the carrier board 61 can also be regarded as the growth substrate of the second color light emitting element 12.

In some embodiments, as shown in FIG. 9d, after the first color light emitting element 11 is transferred to the temporary substrate, the distance between the surface of the first color light emitting element 11 away from the temporary substrate and the temporary substrate is d3, where d2>d3. That is, the distance between the carrier board 61 and the temporary substrate is greater than the height of the first color light emitting element 11, so as to prevent the carrier board 61 from colliding with the first color light emitting element 11.

When performing SLLO, d2 is 30-50 micrometers, which is much larger than the height of the first color light emitting element 11, and the first color light emitting element 11 cannot collide with the second color light emitting element 12 above. In order to improve the yield of the transferred second color light emitting element 12, d2 should be as small as possible, but considering the uniformity of the surface of the adhesive 32 and the precision of the equipment movement platform, d2 must be at least greater than 30 micrometers, in order to achieve mass production.

As shown in FIG. 9f, the third color light emitting element 13 is transferred to the temporary substrate by using the third transfer method.

The relatively dense third color light emitting elements 13 are formed on the third growth substrate 23, and only a part of the third color light emitting elements 13 need to be transferred to the temporary substrate in this step. The third growth substrate 23 is placed over the temporary substrate, and a minimum distance between the third growth substrate 23 and the adhesive 32 is also d2. A laser with a wavelength of 248 nm is used to cooperate with the mask plate 43 to perform SLLO on the third color light emitting element 13 at a specific position. Alternatively, a 266 nm solid-state UV laser is used to perform SLLO by means of galvanometer scanning (no mask required) to form a temporary substrate as shown in FIG. 9g.

The first transfer method is a contact transfer method, which means that when performing SLLO on the first color light emitting elements, the first color light emitting elements are already in contact with the temporary substrate and are bound on the temporary substrate.

The second transfer method and the third transfer method are gap transfer method, which means that when performing SLLO on the second color light emitting element or the third color light emitting element, the second color light emitting element or the third color light emitting element does not contact the temporary substrate, but there is a gap distance between the light emitting element and the temporary substrate.

A reason for using two different transfer methods is that if only the contact transfer method is used, then when transferring the second color light emitting elements, the first color light emitting elements that have been transferred to the temporary substrate will collide with the dense second color light emitting elements on the carrier, causing damage to a large number of light emitting elements. Therefore, the gap transfer method is more suitable than the contact transfer method for the second color light emitting elements and the third color light emitting elements.

When performing SLLO, the patterned surface microstructure on the first growth substrate requires a higher energy density than the flat sheet structure on the carrier and the third growth substrate. The energy density required for the first growth substrate is at least 2000-3000 mJ/cm², and the energy density required by the flat sheet structure is at least 100-300 mJ/cm². The great energy density leads to great impact force and worse carrying effect of the temporary substrate. Therefore, the contact transfer method used for the first color light emitting element can avoid the worsening of the carrying effect caused by the high energy density, so as to ensure a high transfer yield. The second color light emitting element and the third color light emitting element require low energy density, and thus can have a high transfer yield even using the gap transfer method.

It should be noted that the light emitting surface of the second color light emitting element is fixed to the carrier through the release glue. Although the light emitting surface of the second color light emitting element is uneven, the contact surface of the release glue and the carrier is flat, which is equivalent to a flat structure when the SLLO is performed.

In some embodiments, the manufacturing method of the display panel further includes: after the light emitting elements are transferred to the temporary substrate, transferring the light emitting elements of different colors on the temporary substrate to the array substrate using the same transfer method, which is described as follows.

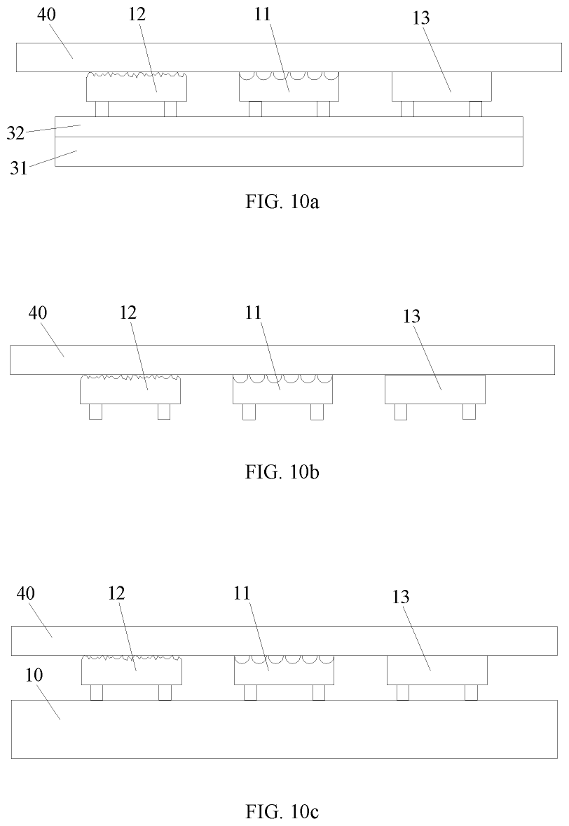

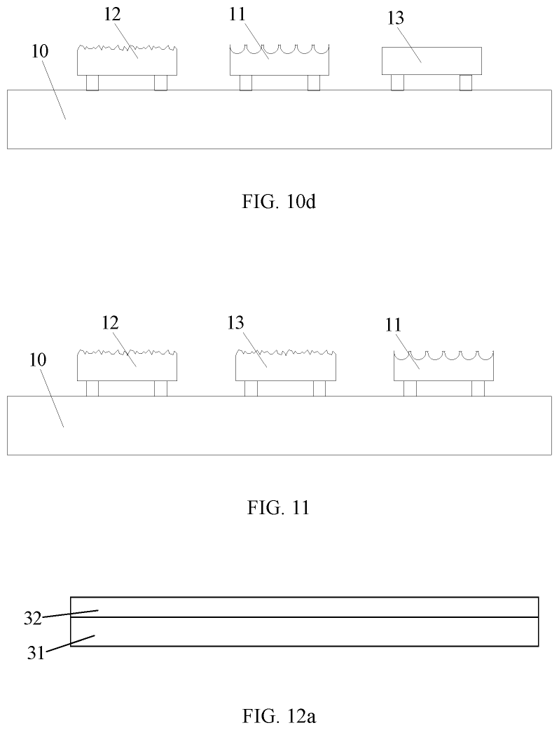

As shown in FIG. 10a, the transfer stamp 40 is used to pick up the first color light emitting element 11, the second color light emitting element 12 and the third color light emitting element 13 on the temporary substrate. For example, the light emitting elements are adsorbed to the lower surface of the transfer stamp 40 through an electrostatic force.

As shown in FIG. 10b, the first color light emitting element 11, the second color light emitting element 12 and the third color light emitting element 13 are removed from the temporary substrate by using the transfer stamp 40.

As shown in FIG. 10c, the first color light emitting element 11, the second color light emitting element 12 and the third color light emitting element 13 adsorbed on the transfer stamp are bound to the array substrate 10.

As shown in FIG. 10d, after the binding is completed, the transfer stamp is removed and a display panel is formed, which includes the array substrate 10 and the light emitting elements of three colors.

The method of manufacturing the display panel provided by the embodiments of the present disclosure can transfer the light emitting elements of three colors to the array substrate together by using the transfer stamp only once. Compared with the related art that uses the transfer stamp three times to transfer the light emitting elements of the three colors respectively, the embodiments of the present disclosure significantly improve the production efficiency of the display panel.

An embodiment of the present disclosure further provides a display panel. The display panel includes light emitting elements, the light emitting elements include a first color light emitting element and a second color light emitting element, the surface microstructure of the first color light emitting element close to the light emitting surface of the display panel is different from the surface microstructure of the second color light emitting element close to the light emitting surface of the display panel. Different surface microstructures are made for light emitting elements of different colors to achieve selective improvement of light efficiency.

In some embodiments, as shown in FIG. 2, the first color light emitting element 11 is a green light emitting element, and the second color light emitting element 12 is a red light emitting element. The surface microstructure of the first color light emitting element 11 includes pits 110 uniformly arranged, and the surface microstructure of the second color light emitting element 12 is a roughened surface microstructure.

The first color light emitting element 11 adopts a surface microstructure of uniformly arranged pits 110, which can improve the lattice matching between sapphire and GaN, reduce the dislocation defect density of GaN, and improve the internal quantum efficiency. In addition, the surface microstructure can also provide many reflective surfaces with different angles to reflect total reflected light, which can improve the external quantum efficiency and the overall luminous efficiency. Especially for green light emitting elements having high total reflectance, the luminous efficiency can be significantly improved.

In some embodiments, the distance between adjacent pits 110 is of a fixed value. That is, all adjacent pits 110 have the same distance to form a relatively uniform surface microstructure, and the first color light emitting element 11 has a relatively uniform luminous effect.

In some embodiments, the maximum width of the pit 110 is less than or equal to 2.7 microns, and the maximum depth of the pit 110 is less than or equal to 1.8 microns. By setting the width of the pits 110 not greater than 2.7 microns, or the depth of the pits 110 not greater than 1.8 microns, the first color light emitting element 11 can have sufficient pits 110, and the light emitted by the first color light emitting element 11 has relatively uniform brightness, which can also improve the external quantum efficiency and improve the overall luminous efficiency.

The second color light emitting element 12 is a red light emitting element, and the second growth substrate used for the red light emitting element is a GaAs substrate, which is not suitable for forming a patterned substrate using DPSS technology or WPSS technology. Therefore, the surface of the second color light emitting element 12 grown on the second growth substrate is flat. Then the second color light emitting element 12 is separated from the second growth substrate and then etched to form a roughened surface microstructure. The roughened surface microstructure is an irregular surface microstructure, which can provide a large number of reflective surfaces with different angles, which can reflect fully reflected light, and thus improve external quantum efficiency and luminous efficiency.

In some embodiments, the display panel further includes a third color light emitting element 13. The third color light emitting element 13 is a blue light emitting element, and the surface of the third color light emitting element 13 facing the light emitting surface of the display panel is a flat surface. Because the blue light emitting element has high light efficiency, the light emitting surface of the blue light emitting element can be a flat surface to simplify the overall manufacturing process of the display panel.

In some embodiments, as shown in FIG. 5, the display panel includes light emitting elements of three colors, the first color light emitting element 11 is a green light emitting element, the second color light emitting element 12 is a red light emitting element, and the third color light emitting element 13 is a blue light emitting element. The surface microstructure of the first color light emitting element 11 includes pits 110 uniformly arranged. The surface microstructures of the second color light emitting element 12 and the third color light emitting element 13 are roughened surface microstructures. Etching the blue light emitting element into a roughened surface microstructure can improve the light efficiency of the blue light emitting element, to improve the overall light efficiency of the display panel.

In some embodiments, as shown in FIG. 7, the display panel includes light emitting elements of three colors, the first color light emitting element 11 is a green light emitting element, the second color light emitting element 12 is a red light emitting element, and the third color light emitting element 13 is a blue light emitting element. The surface microstructure of the first color light emitting element 11 includes pits uniformly arranged. The surface microstructures of the second color light emitting element 12 and the third color light emitting element 13 are flat surfaces. Both the red light emitting element and the blue light emitting element adopt flat surface microstructures, which can simplify the manufacturing process of the display panel while maintaining the overall light efficiency of the display panel.

In some embodiments, as shown in FIG. 8, the display panel includes light emitting elements of three colors, the first color light emitting element 11 is a green light emitting element, the second color light emitting element 12 is a red light emitting element, and the third color light emitting element 13 is a blue light emitting element. The surface microstructures of the first color light emitting element 11 and the third color light emitting element 13 have flat surfaces, and the surface microstructure of the second color light emitting element 12 is a roughened surface microstructure. Both the green light emitting element and the blue light emitting element adopt the surface microstructure of the flat surface, which simplifies the manufacturing process of the display panel while maintaining the overall light efficiency of the display panel.

In some embodiments, the first color light emitting elements are blue light emitting elements, and the second color light emitting elements are one or more of green light emitting elements and red light emitting elements.

As shown in FIG. 11, the display panel includes light emitting elements of three colors, the first color light emitting element 11 is a blue light emitting element, the second color light emitting element 12 is a red light emitting element, and the third color light emitting element 13 is a green light emitting element. The surface microstructure of the first color light emitting element 11 includes pits uniformly arranged, and the surface microstructures of the second color light emitting element 12 and the third color light emitting element 13 are roughened surface microstructures. The surface microstructure of uniformly arranged pits in the blue light emitting element can improve the lattice matching between the sapphire and the GaN, reduce the dislocation defect density of GaN, and improve the internal quantum efficiency. The surface microstructure of uniformly arranged pits can also provide a large number of reflective surfaces with different angles, which can reflect fully reflected light and thus improve the external quantum efficiency. At the same time, the roughened surface microstructure of the red light emitting element and the green light emitting element can also provide a large number of reflective surfaces with different angles, which can reflect fully reflected light, and thus improve the external quantum efficiency and the overall luminous efficiency of the display panel.

Because the surface microstructures of the red light emitting element and the green light emitting element are the same, both the red light emitting element and the green light emitting element can be regarded as the second color light emitting element.

An embodiment of the present disclosure also provides a method for manufacturing the above-mentioned display panel, which includes the transfer process as follows.

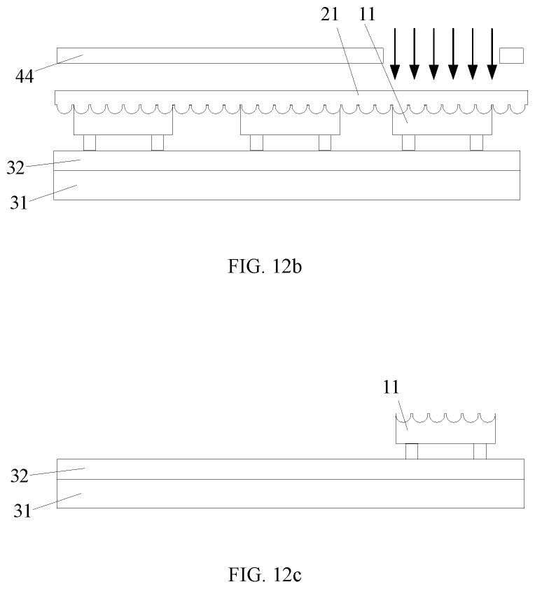

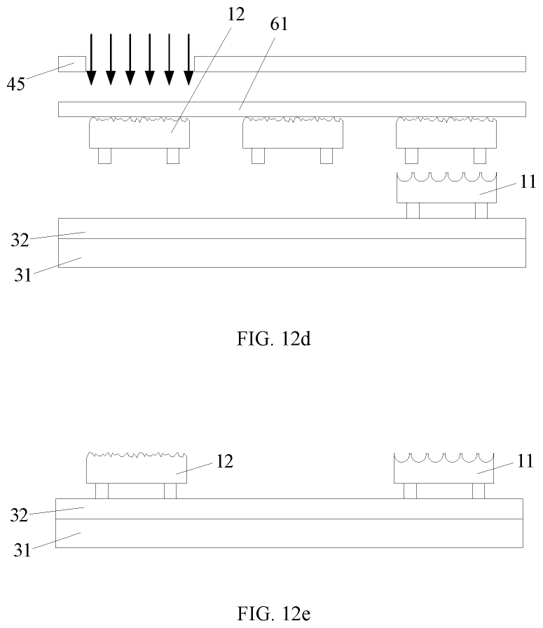

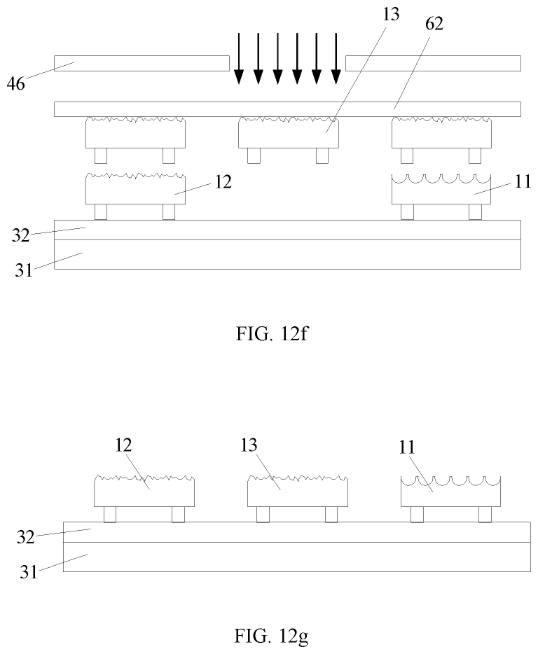

As shown in FIG. 12a, a temporary substrate is provided, where the temporary substrate includes a substrate 31 and an adhesive 32 coated on the substrate 31.

As shown in FIG. 12b, the first color light emitting element 11 is transferred to the temporary substrate by using the first transfer method.

The first color light emitting elements 11 are densely grown on the first growth substrate 21, and only a part of the first color light emitting elements 11 need to be transferred to the temporary substrate in this step. The COW of the first color light emitting elements 11 are bound to the temporary substrate, and then the SLLO is performed by using the mask plate 44 to peel off the bound first color light emitting elements 11 to form a temporary substrate as shown in FIG. 12c.

As shown in FIG. 12d, the second color light emitting element 12 is transferred to the temporary substrate by using the second transfer method.

The carrier board 61 carries the relatively dense second color light emitting elements 12, only a part of which need to be transferred to the temporary substrate in this step. The carrier board 61 is placed above the temporary substrate, and the mask plate 45 is used to perform SLLO on the second color light emitting elements 12 at specific positions to form a temporary substrate as shown in FIG. 12e.

As shown in FIG. 12f, the second transfer method is also to transfer the third color light emitting element 13 to the temporary substrate.

The carrier board 62 carries relatively dense third color light emitting elements 13, only a part of which need to be transferred to the temporary substrate in this step. The carrier board 62 is placed above the temporary substrate, and the mask plate 46 is used to perform SLLO on the third color light emitting elements 13 at specific positions to form a temporary substrate as shown in FIG. 12g.

The contact transfer method used for the first color light emitting element can avoid the worsening of the carrying effect caused by the high energy density, so as to ensure a high transfer yield. The second color light emitting element and the third color light emitting element require low energy density, and thus can have high transfer yield even using the gap transfer method.

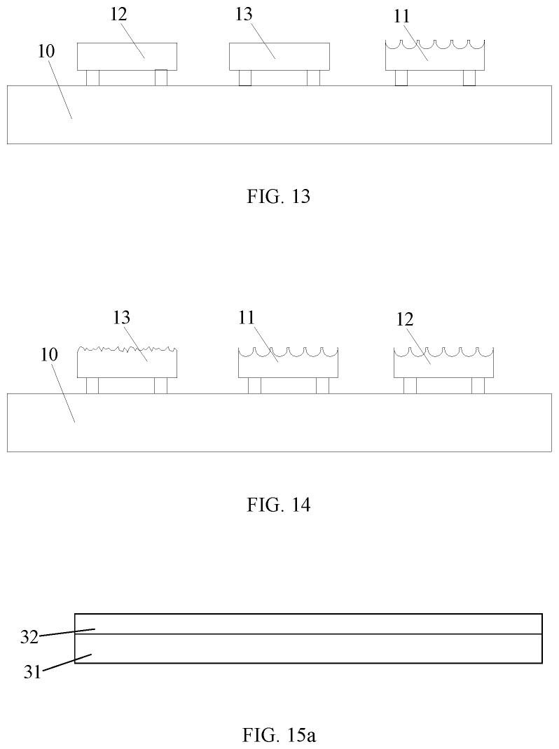

In some embodiments, as shown in FIG. 13, the display panel includes light emitting elements of three colors, the first color light emitting element 11 is a blue light emitting element, the second color light emitting element 12 is a red light emitting element, and the third color light emitting element 13 is a green light emitting element. The surface microstructure of the first color light emitting element 11 includes pits uniformly arranged, and the surface of the second color light emitting element 12 and the third color light emitting element 13 are flat surfaces. Both the red light emitting element and the green light emitting element adopt flat surface microstructures, which can simplify the manufacturing process of the display panel while maintaining the overall light efficiency of the display panel.

In some embodiments, as shown in FIG. 14, the display panel includes light emitting elements of three colors, the first color light emitting element 11 is a green light emitting element, the second color light emitting element 12 is a blue light emitting element, and the third color light emitting element 13 is a red light emitting element. The surface microstructures of the first color light emitting element 11 and the second color light emitting element 12 include pits uniformly arranged, and the surface microstructure of the third color light emitting element 13 is a roughened surface microstructure. The surface microstructure of uniformly arranged pits in the blue light emitting element and the green light emitting element can improve the lattice matching between the sapphire and the GaN, reduce the dislocation defect density of GaN and improve the internal quantum efficiency. The surface microstructure of uniformly arranged pits can further provide a large number of reflective surfaces with different angles which can reflect fully reflected light to improve the external quantum efficiency. At the same time, the red light emitting element adopts a roughened surface microstructure, which can also provide a large number of reflective surfaces with different angles to reflect fully reflected light, which can improve the external quantum efficiency and the overall luminous efficiency of the display panel.

An embodiment of the present disclosure provides a method of manufacturing the above-mentioned display panel, which includes a transfer process as follows.

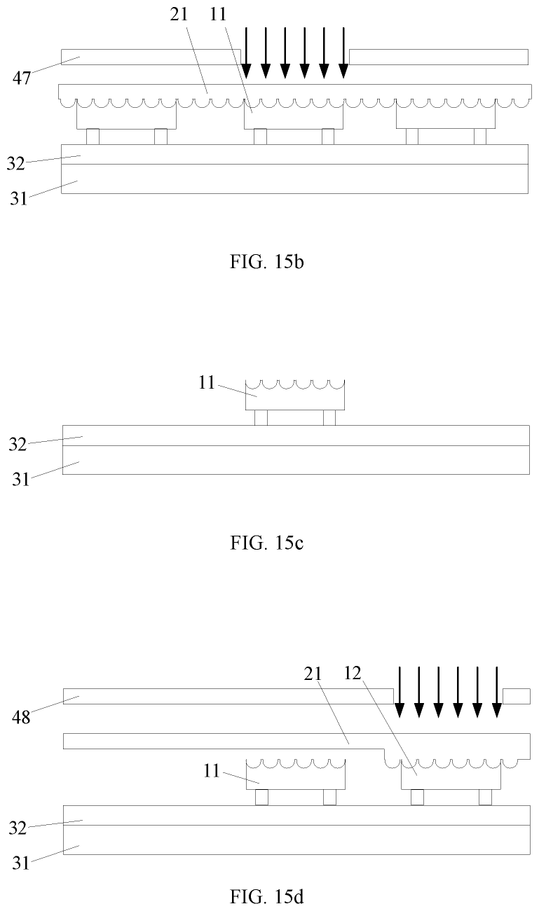

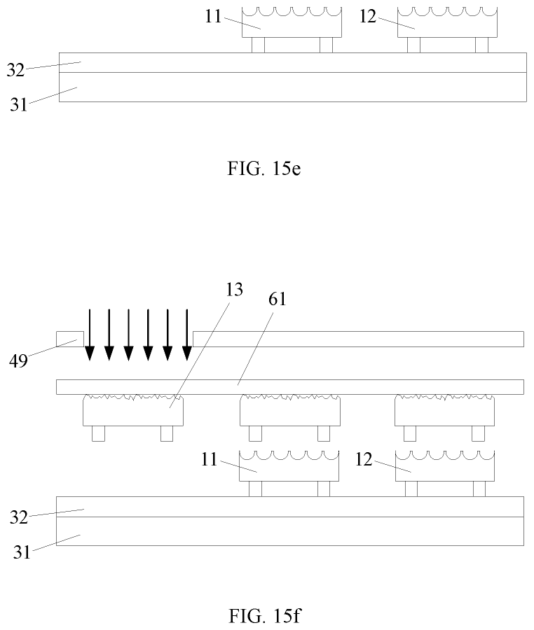

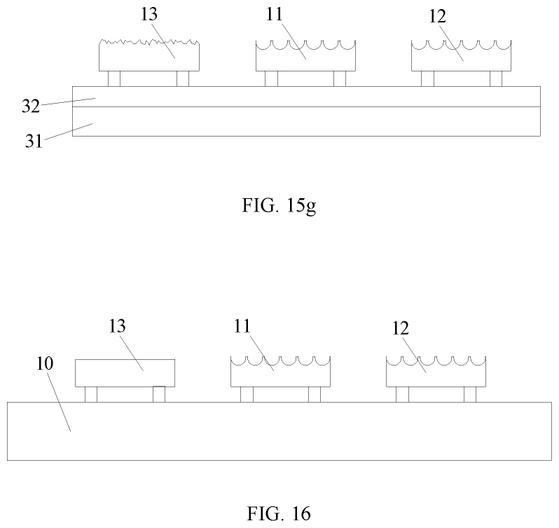

As shown in FIG. 15a, a temporary substrate is provided, which includes a substrate 31 and an adhesive 32 coated on the substrate 31.

As shown in FIG. 15b, the first color light emitting element 11 is transferred to the temporary substrate by using the first transfer method.

The first color light emitting elements 11 are densely grown on the first growth substrate 21, only a part of which need to be transferred to the temporary substrate in this step. The COW of the first color light emitting elements 11 are bound to the temporary substrate, and then the SLLO is performed by using the mask plate 47 to peel off the bound first color light emitting elements 11 to form a temporary substrate as shown in FIG. 15c.

As shown in FIG. 15d, the first transfer method is also used to transfer the second color light emitting element 12 to the temporary substrate.

A small number of second color light emitting elements 12 are grown on the second growth substrate 21. There is no second color light emitting element 12 at the position corresponding to the first color light emitting element 11. The second growth substrate 21 is provided with a concave structure at the position corresponding to the first color light emitting element 11, and when the COW of the second color light emitting element 12 is bound to the temporary substrate, the second growth substrate 21 will not collide with the first color light emitting element 11, ensuring the successful binding of the second color light emitting element 12. Then, the SLLO is performed by using the mask plate 48, to peel off the bound second color light emitting elements 12 to form a temporary substrate as shown in FIG. 15e.

As shown in FIG. 15f, the third color light emitting element 13 is transferred to the temporary substrate by using the second transfer method.

The carrier board 61 carries relatively dense third color light emitting elements 13, only a part of which need to be transferred to the temporary substrate in this step. The carrier board 62 is placed over the temporary substrate, and the mask plate 49 is used to perform SLLO on the third color light emitting elements 13 at specific positions to form a temporary substrate as shown in FIG. 15g.

Both the first color light emitting element and the second color light emitting element adopt the contact transfer method, which can avoid the worsening of the carrying effect caused by the high energy density, so as to ensure a high transfer yield. The third-color light emitting element requires a small energy density, and thus can have a high transfer yield even using the gap transfer method.

In some embodiments, as shown in FIG. 16, the display panel includes light emitting elements of three colors, the first color light emitting element 11 is a green light emitting element, the second color light emitting element 12 is a blue light emitting element, and the third color light emitting element 13 is a red light emitting element. The surface microstructure of the first color light emitting element 11 and the second color light emitting element 12 includes pits uniformly arranged, and the surface microstructure of the third color light emitting element 13 is a flat surface. The surface microstructure of uniformly arranged pits in the blue light emitting element and the green light emitting element can improve the lattice matching between the sapphire and the GaN, which can reduce the dislocation defect density of the GaN, and improve the internal quantum efficiency The surface microstructure of uniformly arranged pits can further provide a large number of reflective surface with different angles, which can reflect fully reflected light to improve the external quantum efficiency. The red light emitting element adopts a light emitting surface with a flat structure, which can simplify the manufacturing process of the display panel.

An embodiment of the present disclosure further provides a display device, including the display panel provided by any one of the foregoing embodiments.

The display devices provided by the embodiments of the present disclosure have the same features as the display panels provided by the above embodiments, and thus can solve the same problems and achieve the same effects.

It should be noted that in this article, relative terms such as “first” and “second” are only used to distinguish one entity or operation from another entity or operation, and do not necessarily require or imply these such actual relationship or order exists between entities or operations. Furthermore, the term “comprises”, “comprises” or any other variation thereof is intended to cover a non-exclusive inclusion and a process, method, article, or apparatus including a set of elements includes not only those elements, but also includes elements not expressly listed, or also include elements inherent in such a process, method, article, or device. Without further limitations, an element defined by the phrase “comprising a . . . ” does not exclude the presence of additional identical elements in the process, method, article or apparatus including said element.

What is claimed is:

1. A method of manufacturing a display panel, comprising:
forming a display panel comprising a plurality of light emitting elements, wherein the plurality of light emitting elements comprises first color light emitting elements and second color light emitting elements;
wherein the method comprises at least one of:
transferring the first color light emitting elements and the second color light emitting elements by different transfer methods,
growing the first color light emitting elements and the second color light emitting elements by different growth substrate patterns, or
making the first color light emitting elements and the second color light emitting elements with different surface microstructures facing a light emitting surface of the display panel.

2. The method according to claim 1, wherein the growing the first color light emitting elements and the second color light emitting elements by different growth substrate patterns comprises:
providing a first growth substrate and a second growth substrate,
growing the first color light emitting elements on the first growth substrate, and
growing the second color light emitting elements on the second growth substrate;
wherein a pattern of the first growth substrate is different from a pattern of the second growth substrate.

3. The method according to claim 2, wherein a surface of the first growth substrate comprises a plurality of protrusions uniformly arranged.

4. The method according to claim 3, wherein a maximum width of the protrusions is less than or equal to 2.7 microns, and/or a maximum depth of the protrusions is less than or equal to 1.8 microns.

5. The method according to claim 1, wherein the transferring the first color light emitting elements and the second color light emitting elements by different transfer methods comprises:
providing a temporary substrate,
transferring the first color light emitting elements from a first growth substrate to the temporary substrate by a first transfer method in which a minimum distance between the first growth substrate of the first color light emitting elements and the temporary substrate is d1; and
transferring the second color light emitting elements from a second growth substrate to the temporary substrate by a second transfer method in which a minimum distance between the second growth substrate of the second color light emitting elements and the temporary substrate is d2, wherein d1<d2.

6. The method according to claim 5, wherein the first transfer method is a contact transfer method.

7. The method according to claim 5, wherein the transferring the first color light emitting elements and the second color light emitting elements by different transfer methods further comprises:
transferring the first color light emitting elements to the temporary substrate before transferring the second color light emitting elements to the temporary substrate.

8. The method according to claim 5, wherein before transferring the second color light emitting elements to the temporary substrate by the second transfer method, the method further comprises etching a surface of the second color light emitting elements to form a surface microstructure.

9. The method according to claim 5, wherein after the first color light emitting elements are transferred to the temporary substrate, a distance between the temporary substrate and a surface of the first color light emitting elements away from the temporary substrate is d3, d2>d3.

10. The method according to claim 9, wherein after transferring the plurality of light emitting elements to the temporary substrate, transferring the first color light emitting elements and the second color light emitting elements from the temporary substrate to an array substrate using a same transfer method.

11. The method according to claim 5, wherein the first color light emitting elements are green light emitting elements, and the second color light emitting elements are red light emitting elements.

12. The method according to claim 1, wherein the making the first color light emitting elements and the second color light emitting elements with different surface microstructures facing a light emitting surface of the display panel comprises:
making the first color light emitting elements with a surface microstructure having a plurality of pits uniformly arranged; and/or,
making the second color light emitting elements with a roughened surface microstructure.

13. The method according to claim 12, wherein the first color light emitting elements are green light emitting elements, and the second color light emitting elements are red light emitting elements.

14. A display panel, comprising:
a plurality of light emitting elements, wherein the plurality of light emitting elements comprise first color light emitting elements and second color light emitting elements, a surface microstructure of the first color light emitting elements facing a light emitting surface of the display panel is different from a surface microstructure of the second color light emitting elements facing the surface microstructure of the light emitting surface of the display panel.

15. The display panel according to claim 14, wherein the surface microstructure of the first color light emitting elements comprises a plurality of pits uniformly arranged; and/or,
the surface microstructure of the second color light emitting elements is a roughened surface microstructure.

16. The display panel according to claim 15, wherein a maximum width of the pits is less than or equal to 2.7 microns, and/or a maximum depth of the pits is less than or equal to 1.8 microns.

17. The display panel according to claim 14, wherein the first color light emitting elements are blue light emitting elements, and the second color light emitting elements are green light emitting elements and/or red light emitting elements.

18. The display panel according to claim 14, wherein the first color light emitting elements are green light emitting elements, and the second color light emitting elements are red light emitting elements.

19. The display panel according to claim 18, further comprising third color light emitting elements, and a surface of the third color light emitting elements facing the light emitting surface of the display panel is a flat surface.

20. A display device, comprising:
a display panel, wherein the display panel comprises a plurality of light emitting elements, the plurality of light emitting elements comprise first color light emitting elements and second color light emitting elements, a surface microstructure of the first color light emitting elements facing a light emitting surface of the display panel is different from a surface microstructure of the second color light emitting elements facing the surface microstructure of the light emitting surface of the display panel.
